(19) United States
(12) Patent Application Publication
(10) Pub. No.: US 2010/0013080 A1
(43) Pub. Date: Jan. 21, 2010

(54) SEMICONDUCTOR DEVICE PACKAGE WITH INSULATOR RING

(76) Inventors: Wen-Cheng CHIEN, Taoyuan (TW); Wang-Ken Huang, Taoyuan (TW)

Correspondence Address: BIRCH STEWART KOLASCH & BIRCH, PO BOX 747, FALLS CHURCH, VA, 22040-0747, US

(21) Appl. No.: 12/565,470

(22) Filed: Sep. 23, 2009

Related U.S. Application Data
(62) Division of application No. 11/987,228, filed on Nov. 28, 2007.

(30) Foreign Application Priority Data
Aug. 8, 2007 (TW) 096129207

(51) Int. Cl. H01L 23/498

(52) U.S. Cl. 257/690; 257/E23.069

(57) ABSTRACT

Embodiments provide a semiconductor device package and a method for fabricating thereof. The package includes a silicon substrate having a semiconductor device and a metal layer thereon; an insulator ring formed in the silicon substrate and surrounding a portion of a silicon material below the metal layer; and a conductive layer disposed below a backside of the silicon substrate and extended to contact the portion of the silicon material surrounded by the insulator ring below the metal layer.

### CROSS REFERENCE TO RELATED APPLICATIONS

This application is a divisional Application of pending U.S. patent application Ser. No. 11/987,228, filed Nov. 28, 2007, which claims priority of Taiwan Patent Application No. 096129207, filed on Aug. 8, 2007, the entirety of which are incorporated by reference herein.

### BACKGROUND OF THE INVENTION

1. Field of the Invention

The invention relates to semiconductor device packages, and more particularly to a semiconductor device package with insulator ring.

2. Description of the Related Art

Photosensitive integrated circuits play an important role in image sensor devices which are widely used in consumer devices, such as digital cameras, digital video recorders, mobile phones, and portable devices. With consumer's demanding lighter and lighter portable devices, requirement to reduce the dimensions of image sensor packages has increased.

FIG. 1 is a cross section of a conventional image sensor package 1. In FIG. 1, a substrate 2 with an image sensor device 4 electrically connected to an extending bonding pad 6 thereon is provided. A covering plate 8 is then disposed on the substrate 2 followed by the substrate 2 being attached to a carrying plate 14. As shown in FIG. 1, a conductive layer 10 is formed on a backside of the carrying plate 14 and extended to the sidewalls of the carrying plate 14 and the substrate 2 electrically connects the extending bonding pad 6 to a solder ball 12. The image sensor package has large dimensions since the image sensor package structures require both the substrate and the carrying plate which have a certain thickness. Moreover, because the conductive layer is formed close to an exterior area of the image sensor package, for example the sidewalls of the substrate and the carrying plate, damage to the conductive layer may occur during fabrication, resulting in device failure.

Thus, an image sensor package and fabrication method thereof eliminating the described problems is needed.

### BRIEF SUMMARY OF INVENTION

Accordingly, the invention provides a semiconductor device package. An exemplary embodiment of the semiconductor device package comprises a silicon substrate having a semiconductor device and a metal layer thereon; an insulator ring formed in the silicon substrate and surrounding a portion of a silicon material below the metal layer; and a conductive layer disposed below a backside of the silicon substrate and extended to contact the portion of the silicon material surrounded by the insulator ring below the metal layer.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a cross section of a conventional image sensor package;

FIGS. 2-7 are schematic views illustrating a method for fabricating an image sensor package according to an embodiment of the invention; and

FIG. 8 is a flow chart of a method for fabricating an image sensor package according to the embodiment of the invention.

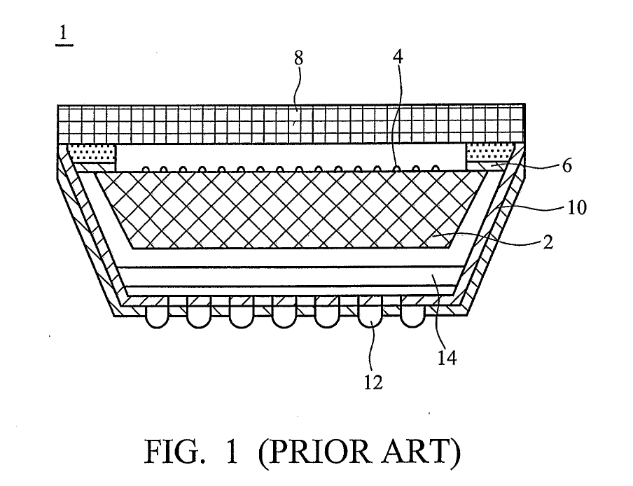

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

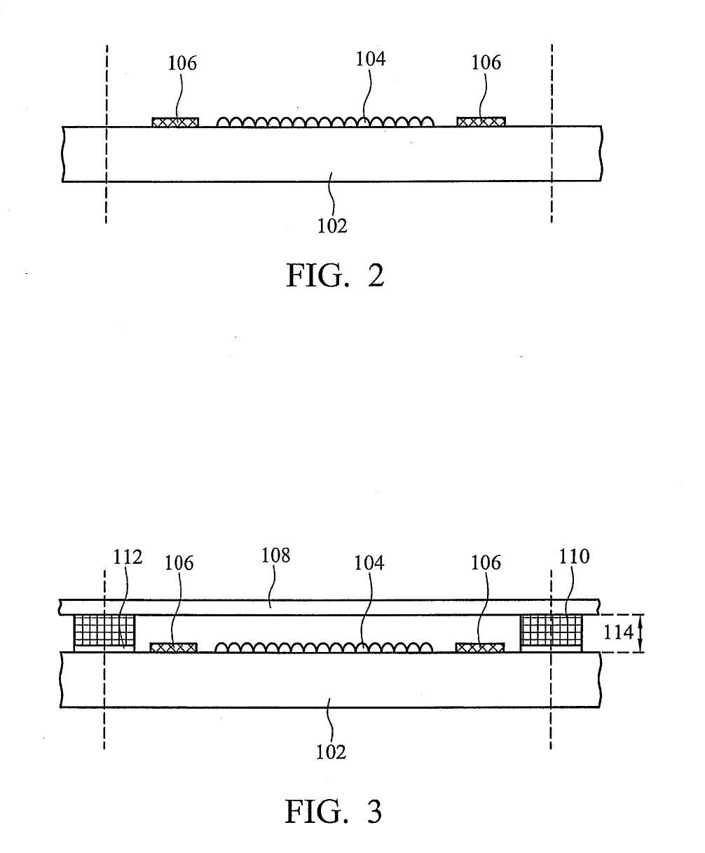

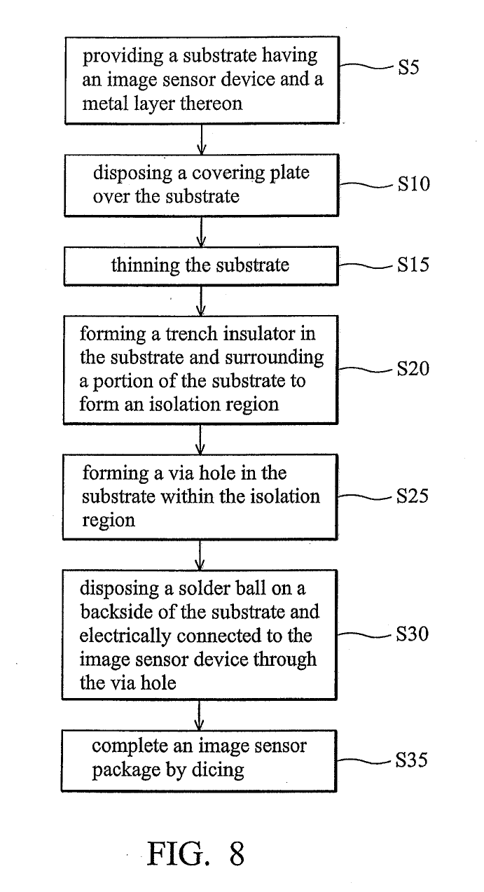

FIGS. 2-7 are schematic views illustrating a method for fabricating an image sensor package according to an embodiment of the invention. The invention will be described with respect to a preferred embodiment of an image sensor package and the fabrication method thereof. The invention may also be applied, however, to any other semiconductor devices. FIG. 8 is a flow chart of a method for fabricating an image sensor package according to the embodiment of the invention.

Referring to FIG. 2, a substrate 102 made of a material, such as silicon, is provided with an image sensor device 104 and a metal layer 106 thereon, which are electrically connected to each other. In one embodiment, the image sensor device 104 is fabricated on the substrate 102 by a complementary metal-oxide-semiconductor (CMOS) process. Then, the metal layer 106 is formed on the substrate 102 by a metallization process and is electrically connected to the image sensor device 104.

In the case, the image sensor device 104 may be complementary metal-oxide-semiconductor device or charge-coupled device (CCD) for capturing pictures or images. The metal layer 106, preferably, is made of a conductive material such as copper (Cu), aluminum (Al) or tungsten (W).

Note that while the metal layer 106 illustrated as a signal layer in the embodiments of the invention, the metal layer 106 may also be an interconnection structure comprising of dielectric layers sandwiched between numbers of metal layers, whereby the metal layers are connected to each other by the metal plugs. In one embodiment of the interconnection structure, the bottommost metal layer is directly formed on the substrate and the uppermost metal layer is stacked over the bottommost metal layer to electrically connect the image sensor device and the bottommost metal layer.

Referring to FIG. 3, a covering plate 108 is disposed over the substrate 102. In some embodiments, a support member 110, such as epoxy, polyimide (PI), photoresist or any other suitable materials, is formed on the covering plate 108. Then, an adhesive layer 112 such as a material comprising epoxy is coated on the support member 108 followed by bonding the covering plate 108 to the substrate 102 to form a distance 114 therebetween. Preferably, the covering plate 108 is made of a transparent material such as glass, quartz or any other suitable materials. Additionally, a polymer material such as polyester may also be possible to be used in covering plate 108.

Alternatively, the support member 110 may be formed on the substrate 102 followed by coating of the adhesive layer 112 on the support member 110. Next, the covering plate 108 is bonded to the support member 110 to dispose the covering plate 108 over the substrate 102.

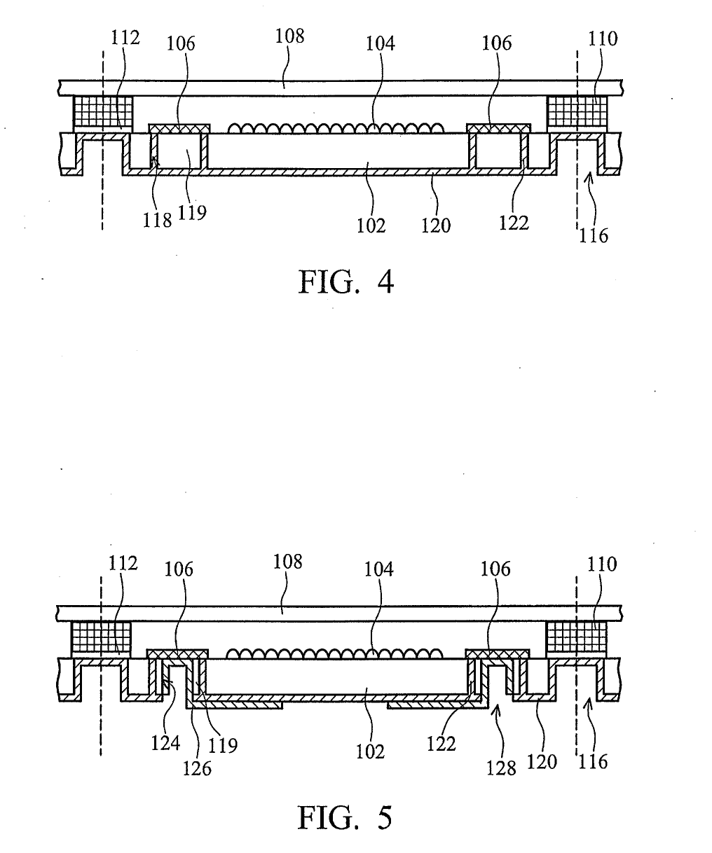

After bonding, the substrate 102 is then thinned. In one embodiment, the substrate 102 is ground from its backside by, for example chemical mechanical polishing (CMP) to thin the substrate 102 to an adequate thickness. Preferably, the thickness is less than 150 μm, for example. After thinning, notching the substrate 102 from its backside is executed to form a trench 116 in the substrate 102, as shown in FIG. 4.

In FIG. 4, a trench insulator 122 is formed in the substrate 102. In some embodiments, etching the backside of the substrate 102 is executed by, for example a dry-etching to form a trench 118 in the substrate 102, in which the trench 118 surrounds a portion of the substrate 102. Next, an isolating layer 120, such as silicon oxide, silicon nitride, silicon oxynitride or any other suitable insulators, is formed on the backside of the substrate 102 and extends to the trench 118 to form the trench insulator 122 which surrounds an isolation region 119. It is understood that a patterned photoresist (not shown) is formed on the backside of the substrate 102 prior to dry-etching to mask a portion of the substrate 102 and expose the other portion of the substrate 102 for removal.

In one embodiment, a laser drilling step is also possible to be used in formation of the trench 118 followed by depositing the isolating layer 120 in the trench 118 to form the trench insulator 122 and the isolation region 119. Note that the isolation region 119 surrounded by the trench insulator 122, is located in an area below and corresponding to the metal layer 106.

Referring to FIG. 5, a via hole 128 is formed in the isolation region 119 of the substrate 102. In one embodiment, a portion of the isolating layer 120, which covers the isolation region 119, is removed to expose a surface of the substrate 102 in the isolation region 119. Next, a hole 124 is formed by, for example dry-etching, laser drilling or any other suitable manners. Thereafter, a conductive layer 126 is formed on the backside of substrate 102 and extends to the hole 124 to form the via hole 128 in electrical connection with the metal layer 106. Note that the trench insulator 122 surrounds the via hole 128 for isolation.

In some embodiments, a conductive material layer (not shown), such as aluminum (Al), copper (Cu) or nickel (Ni), is conformally formed on the backside of the substrate 102 and extends to the hole 124 to electrically connect to the metal layer 106 by, for example sputtering, evaporating, electroplating or electroless plating. The conductive material layer is then patterned by photolithography/etching to form the conductive layer 126 and the via hole 128. Note that a signal conductive path of an image sensor package later formed can be redistributed by the patterning step to the conductive material layer.

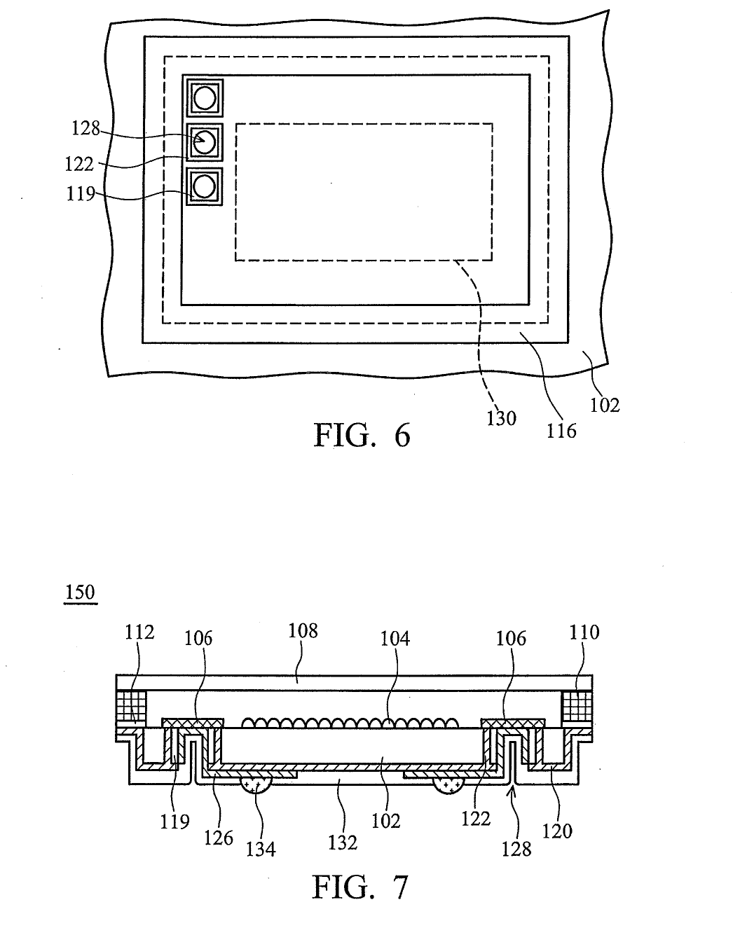

FIG. 6 is a top view of a backside of the semi-finished image sensor package illustrated in FIG. 5. In FIG. 6, several elements shown in FIG. 5 are omitted for simple, clear descriptions. Referring to FIG. 6, the substrate 102 is divided into several dies through the trench 116. Each die comprises an image sensor device region 130, as a dotted line shows in FIG. 6, where the image sensor device 104 (shown in FIG. 5) is located. Moreover, the trench insulator 122, the isolation region 119 and the via hole 128 are located at an area outside of the image sensor region device 130, in which the trench insulator 122 surrounds the isolation region 119 where the via hole 128 is formed. Specifically, the trench insulator 122 does not only surround the isolation region 119, but also the via hole 128.

Note that although several trench insulators 122 and via holes 128 are shown in FIG. 6. In a practical embodiment, however, numerous trench insulators 122 and via holes 128 may surround the image sensor device region 130. Moreover, geometric shape of the isolation region 119 surrounded by the trench insulator 122, is a rectangular shape. However, geometric shape of the isolation region 119 may also be a circular shape. In this case, the trench insulator 122 and the via hole 128 are concentric circles.

Referring to FIG. 7, a solder mask 132 is coated on the backside of the substrate 102, covers the conductive layer 126 and then patterned to expose a portion of the conductive layer 126. Next, a solder ball 134 is disposed on the conductive layer 126 and further connects to the metal layer 104 by the via hole 128. In one embodiment, after the solder mask 132 is formed, a solder material (not shown) is coated on the exposed conductive layer 126 followed by performing a reflow step to form the solder ball 134 on the conductive layer 126. Following the described steps, an individual die is cut out along a predetermined cutting line by a cutter. Thus, an image sensor package 150, as shown in FIG. 7, is complete. Alternatively, a dry-etching step may also be possible to be used in cutting out the individual die.

FIG. 7 is a cross section of an image sensor package 150 according to an embodiment of the invention. In FIG. 7, a substrate 102 is provided with an image sensor device 104 and a metal layer 106 formed thereon. A trench insulator 122 is formed in the substrate 102 and surrounds a portion of the substrate 102 to form an isolation region 119. Referring to FIG. 7, a via hole 128 is formed in the isolation region 119 of the substrate 102, electrically connecting the metal layer 106 to a solder ball 134. A covering plate 108 is then disposed over the substrate 102.

In the image sensor package according to the embodiment of the invention, because the metal layer connects to the via hole within the isolation region, a signal from the image sensor device is transmitted to an exterior circuit via the metal layer, the via hole and the conductive layer, rather than going around the sidewalls of the substrate to transmit the signal. Thus, a signal conductive path to the image sensor device is shortened. Moreover, because it is unnecessarily to form the conductive layer close to an exterior area of the image sensor package, damage to the conductive layer during fabrication is also reduced, thereby improving fabrication yield.

FIG. 8 is a flow chart of a method for fabricating an image sensor package according to an embodiment of the invention. Referring to FIG. 8, the method comprises: providing a substrate having an image sensor device and a metal layer thereon, as shown in step S5; disposing a covering plate over the substrate, as shown in S10; thinning the substrate, as shown in S15; forming a trench insulator in the substrate, whereby the trench insulator surrounds a portion of the substrate to form an isolation region, as shown in S20; forming a via hole in the substrate within the isolation region, as shown in S25; disposing a solder ball on a backside of the substrate, electrically connected to the image sensor device through the via hole, as shown in S30; and complete an image sensor package by dicing, as shown in S35.

Note that because the substrate is thinned, the overall thickness of the image sensor package is reduced. Thus, the image sensor package according to the embodiment of the invention has relatively small dimensions. Moreover, because extra steps, such as the attaching step for bonding a chip to a carrying plate or the etching step for separating the chip are not required, fabrication of the image sensor package is simplified and costs are reduced.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device package, comprising:
a silicon substrate having a semiconductor device and a metal layer thereon;
an insulator ring formed in the silicon substrate and surrounding a portion of a silicon material below the metal layer; and
a conductive layer disposed below a backside of the silicon substrate and extended to contact the portion of the silicon material surrounded by the insulator ring below the metal layer.

2. The semiconductor device package as claimed in claim 1, further comprising:
a covering plate disposed over the silicon substrate; and
a support member located between the covering plate and the silicon substrate.

3. The semiconductor device package as claimed in claim 1, further comprising a solder ball formed below the backside of the silicon substrate, electrically connecting to the conductive layer.

4. The semiconductor device package as claimed in claim 1, wherein the silicon substrate has a thickness less than about 150 μm.

5. The semiconductor device package as claimed in claim 1, wherein the conductive layer passes through the portion of the silicon material and electrically connects the metal layer.

6. The semiconductor device package as claimed in claim 1, further comprising an insulating layer between the conductive layer and the backside of the silicon substrate.
